(19) United States
(12) Patent Application Publication
(10) Pub. No.: US 2015/0194585 A1
(43) Pub. Date: Jul. 9, 2015

(54) LIGHT EMITTING DEVICE PACKAGE AND MANUFACTURING METHOD THEREOF

(71) Applicants: LUMENS CO., LTD, Yongin-si (KR); WAVENICS, INC, Ansan-si (KR)

(72) Inventors: Kyoungmin KIM, Seoul (KR); Yongwook CHO, Yongin-si (KR); Sunghwan YOO, Seoul (KR); Myeongkook GONG, Yongin-si (KR)

(21) Appl. No.: 14/585,824

(22) Filed: Dec. 30, 2014

(30) Foreign Application Priority Data
Jan. 8, 2014 (KR) 10-2014-0002174

(51) Int. Cl. H01L 33/62; H01L 33/58; H01L 33/54; H01L 33/60

(52) U.S. Cl. CPC H01L 33/62; H01L 33/60; H01L 33/58; H01L 33/54; H01L 2933/0066; H01L 2933/0058; H01L 2933/005

(57) ABSTRACT

Provided are a light emitting device package usable as a display or lighting device, and a method of manufacturing the same. The method may include a raw plate preparing step for preparing a raw plate formed of a metallic material, a raw plate shaping step for shaping the raw plate into a substrate strip, a surface-treating step for surface-treating the substrate strip, an insulating layer forming step for forming an insulating layer on the surface-treated substrate strip, an electrode layer forming step for forming a first electrode layer and a second electrode layer separated by an electrode separating line, on the insulating layer formed on a die of the substrate strip, a light emitting device mounting step for mounting a light emitting device on the first and second electrode layers, and a bridge cutting step for cutting a cutting line of the first bridge and a cutting line of the second bridge to individualize the light emitting device and the die of the substrate strip into the light emitting device package.

### CROSS-REFERENCE TO RELATED PATENT APPLICATION

This application claims priority to and the benefit of Korean Patent Application No. 10-2014-0002174 filed in the Korean Intellectual Property Office on Jan. 8, 2014, the entire contents of which are incorporated herein by reference.

### BACKGROUND

1. Field

The present invention relates to a light emitting device package and a method of manufacturing the same and, more particularly, to a light emitting device package usable as a display or lighting device, and a method of manufacturing the same.

2. Description of Related Technology

A light emitting diode (LED) refers to a kind of semiconductor device capable of realizing a light of various colors by configuring a light emitting source through forming a PN diode from a compound semiconductor. Such a light emitting device is advantageous in that it has a long life, miniaturization and weight-lightening are enabled, and low voltage driving is possible. In addition, such a light emitting device is robust to a shock and vibration, and warm-up time and complex driving are not necessary. The light emitting device may be applied to a backlight unit or various lighting devices by being mounted on a substrate or a lead frame in various types, packaged, and then modularized according to various uses.

### SUMMARY

In a conventional light emitting device package, when a substrate formed of a metallic material is used, an insulating layer should be formed on the surfaces of the substrate. However, small cracks are generated at structurally weak corners and cut parts of the insulating layer and propagate to the whole insulating layer or the substrate. As such, product properties are greatly degraded.

The present invention provides a light emitting device package capable of preventing generation of small cracks in an insulating layer and preventing propagation of small cracks generated near cut surfaces, to other parts, and a method of manufacturing the same. However, the above technical problem is illustrative only and the scope of the present invention is not limited thereto.

According to an aspect of the present invention, there is provided a method of manufacturing a light emitting device package, the method may include a raw plate preparing step for preparing a raw plate formed of a metallic material; a raw plate shaping step for shaping the raw plate into a substrate strip to form a first rail and a second rail at a side and another side of the raw plate, respectively, to form dies at a middle part of the raw plate, to form at least one first bridge between the first rail and each die, and to form at least one second bridge between the second rail and the die; a surface-treating step for surface-treating the substrate strip; an insulating layer forming step for forming an insulating layer on the surface-treated substrate strip; and an electrode layer forming step for forming a first electrode layer and a second electrode layer separated by an electrode separating line, on the insulating layer formed on the die of the substrate strip.

In the surface-treating step, the substrate strip may be dipped into an etchant and moved back and forth in a direction perpendicular to a length direction of the substrate strip to round off corners of the dies of the substrate strip.

In the insulating layer forming step, the insulating layer may be formed by oxidizing surfaces of the substrate strip formed of an aluminum material, using an anodizing method.

The electrode layer forming step may include a first mask disposition step for disposing a first mask having a first pattern on the insulating layer such that upper parts of the first and second electrode layers are formed on the insulating layer formed on a top surface of the die of the substrate strip; an upper electrode forming step for forming the upper parts of the first and second electrode layers on the insulating layer through the first pattern of the first mask by using a sputtering method; a second mask disposition step for disposing a second mask having a second pattern on the insulating layer such that lower parts of the first and second electrode layers are formed on the insulating layer formed on a bottom surface of the die of the substrate strip; and a lower electrode forming step for forming the lower parts of the first and second electrode layers on the insulating layer through the second pattern of the second mask by using a sputtering method.

Side clearance holes may be formed at the first pattern of the first mask such that the upper and lower parts of the first and second electrode layers are electrically connected to each other, in the first mask disposition step, a first side electrode may be formed on side surfaces of the die of the substrate strip through the side clearance holes, in the upper electrode forming step, side clearance holes may be formed at the second pattern of the second mask, in the second mask disposition step, and a second side electrode may be formed on the side surfaces of the die of the substrate strip through the side clearance holes, to be electrically connected to the first side electrode, in the lower electrode forming step.

The method may further include a dam forming step for forming a ring-shaped dam around reflection parts of the first and second electrode layers; a light emitting device mounting step for mounting a light emitting device on the first and second electrode layers; and a lens forming step for coating or dispensing a lens material or a phosphor material inside the dam to allow a lens or a phosphor to surround the light emitting device, after the electrode layer forming step.

The method may further include a light emitting device mounting step for mounting a light emitting device on the first and second electrode layers; and a bridge cutting step for cutting a cutting line of the first bridge and a cutting line of the second bridge to individualize the light emitting device and the die of the substrate strip into the light emitting device package, wherein, in the bridge cutting step, the cutting lines of the first and second bridges spaced apart from the die by a margin length are cut to prevent small cracks generated when the first and second bridges are cut from propagating to the die.

In the insulating layer forming step, an insulating layer mask may be disposed such that the insulating layer is not formed on part of the surfaces of the substrate strip.

In the electrode layer forming step, a conductive paste may be printed or pad printed to form the first and second electrode layers.

According to another aspect of the present invention, there is provided a light emitting device package including a substrate formed of a metallic material and having rounded corners; an insulating layer formed on surfaces of the substrate; a first electrode layer and a second electrode layer formed on the insulating layer and separated by an electrode separating line; a light emitting device mounted on the first and second electrode layers; and bridges having cut surfaces at sides thereof and protruding from side surfaces of the substrate or the insulating layer by a margin length to prevent small cracks generated when a substrate strip is cut from propagating to the substrate or the insulating layer.

According to an embodiment of the present invention, by rounding off the corners of a substrate, generation of small cracks may be prevented and propagation of small cracks generated at cut surfaces, to other parts may also be prevented. As such, product performance and durability may be greatly improved and high-quality products may be produced. However, the above effects are illustrative only and the scope of the present invention is not limited thereto.

### BRIEF DESCRIPTION OF THE DRAWINGS

FIG. 1 is a perspective view of a light emitting device package according to an embodiment of the present invention.

FIG. 2 is a cross-sectional view taken along line II-II of FIG. 1.

FIG. 3 is a side elevational view of the light emitting device package of FIG. 1.

FIG. 4 is a plan view showing a raw plate preparing step in a method of manufacturing the light emitting device package of FIG. 1, according to an embodiment of the present invention.

FIG. 5 is a cross-sectional view taken along line X-X of FIG. 4.

FIG. 6 is a plan view showing a raw plate shaping step in the method of manufacturing the light emitting device package of FIG. 1, according to an embodiment of the present invention.

FIG. 7 is a cross-sectional view taken along line VII-VII of FIG. 6.

FIG. 8 is a plan view showing a surface-treating step in the method of manufacturing the light emitting device package of FIG. 1, according to an embodiment of the present invention.

FIG. 9 is a cross-sectional view taken along line IX-IX of FIG. 8.

FIG. 10 is a plan view showing an insulating layer forming step in the method of manufacturing the light emitting device package of FIG. 1, according to an embodiment of the present invention.

FIG. 11 is a cross-sectional view taken along line XI-XI of FIG. 10.

FIG. 12 is a plan view showing a first mask disposition step of an electrode layer forming step in the method of manufacturing the light emitting device package of FIG. 1, according to an embodiment of the present invention.

FIG. 13 is a cross-sectional view taken along line XIII-XIII of FIG. 12.

FIG. 14 is a plan view showing an upper electrode forming step or a lower electrode forming step of the electrode layer forming step in the method of manufacturing the light emitting device package of FIG. 1, according to an embodiment of the present invention.

FIG. 15 is a cross-sectional view taken along line XV-XV of FIG. 14.

FIG. 16 is a plan view showing a dam forming step in the method of manufacturing the light emitting device package of FIG. 1, according to an embodiment of the present invention.

FIG. 17 is a cross-sectional view taken along line XVII-XVII of FIG. 16.

FIG. 18 is a plan view showing a lens forming step in the method of manufacturing the light emitting device package of FIG. 1, according to an embodiment of the present invention.

FIG. 19 is a cross-sectional view taken along line XIX-XIX of FIG. 18.

FIG. 20 is a plan view showing a bridge cutting step in the method of manufacturing the light emitting device package of FIG. 1, according to an embodiment of the present invention.

FIG. 21 is a flowchart of a method of manufacturing the light emitting device package of FIG. 1, according to an embodiment of the present invention.

### DETAILED DESCRIPTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to a person having ordinary skill in the art. In the drawings, the thicknesses of layers and regions are exaggerated for clarity.

It will also be understood that when an element such as layer, region or substrate is referred to as being “on”, “connected to”, “stacked on” or “coupled to” other element, it may be directly “on”, “connected to”, “stacked on” or “coupled to” the other element, or intervening element may also be present therebetween. On the other hand, when an element is referred to as being “directly on”, “directly connected to” or “directly coupled to” other element, it should nbe construed that no intervening elements exist therebetween. Like reference numerals in the drawings denote like elements. As used herein, the term “and/or” refers to one of or a combination of at least two listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Furthermore, relative terms such as “upper”, “above”, “lower”, or “under” may be used herein to describe the relationship between one element and the other element(s) as shown in the drawings. It should be understood that the relative terms are intended to include other directions in addition to the directions shown in the drawings. For example, when an element is turned upside down in the drawings, elements that are depicted to be disposed on an upper surface of the other element will be disposed on a lower surface of the other element. Therefore, the illustrative term “upper” may mean “upper” or “lower”, depending on a particular direction in the drawings. When an element is directed to another direction (rotated at a right angle with reference to other direction), descriptions in the specification will be construed accordingly.

The terminology used herein is for the purpose of describing particular embodiments and is not intended to limit the invention. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing.

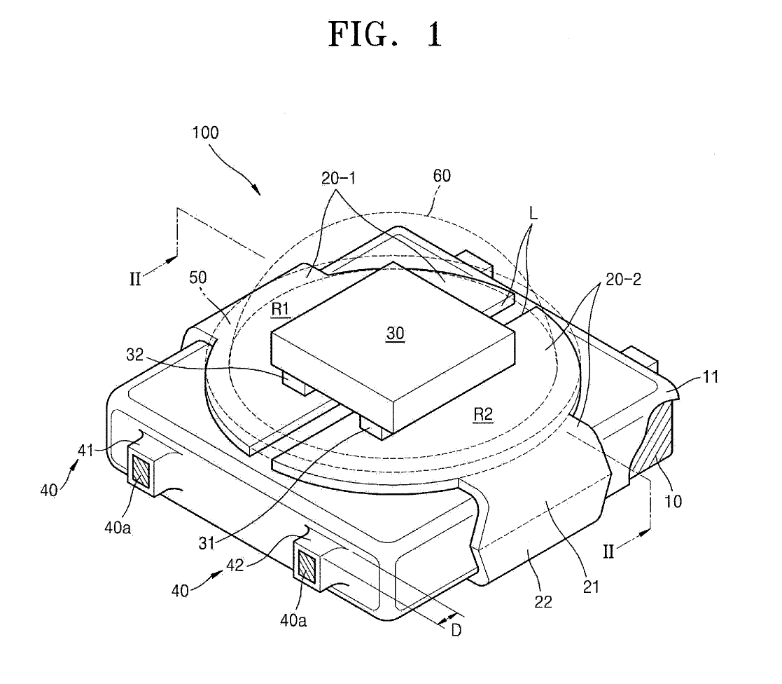

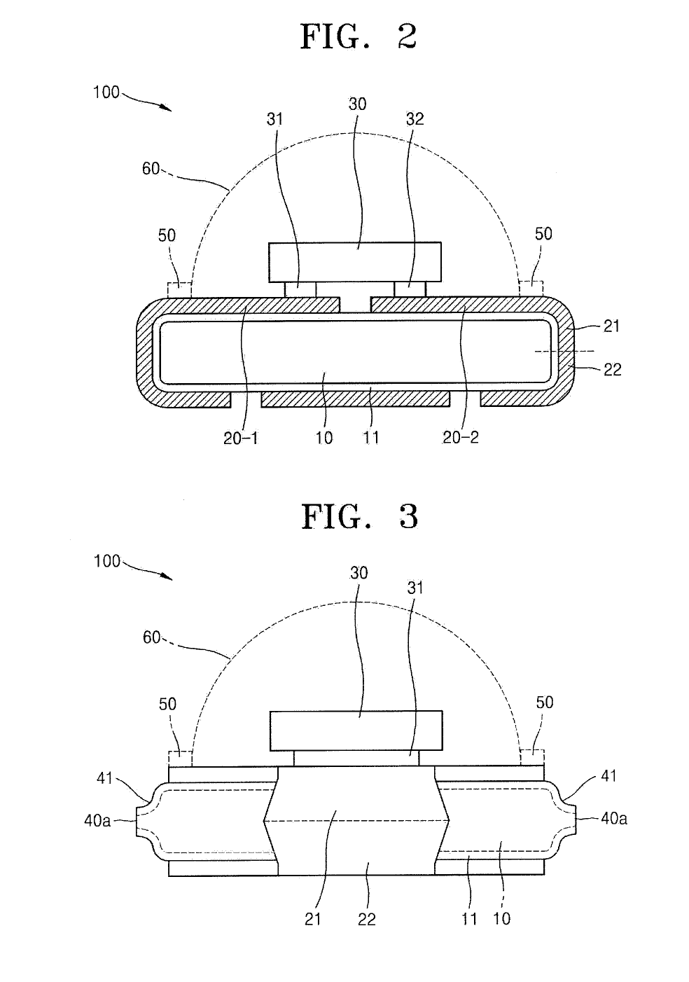

FIG. 1 is a perspective view of a light emitting device package 100 according to an embodiment of the present invention. FIG. 2 is a cross-sectional view taken along line II-II of FIG. 1, and FIG. 3 is a side elevational view of the light emitting device package 100 of FIG. 1.

Initially, as illustrated in FIGS. 1 to 3, the light emitting device package 100 according to an embodiment of the present invention may include a substrate 10, an insulating layer 11, a first electrode layer 20-1, a second electrode layer 20-2, a light emitting device 30 and bridges 40.

Here, the substrate 10 may be a structure formed of a metallic material and having rounded corners.

The corners of the substrate 10 are rounded not only to allow the insulating layer 11 easily to be easily formed on the rounded corners of the substrate 10 but also to radically prevent concentration of small cracks on the corners even when external impacts are exerted or internal stresses are created, by forming the corners in a structurally strong curved or domed shape.

The curvature radius of the rounded corners may vary depending on the size, shape, material, processing condition, etc. of the substrate 10. Accordingly, a designer may optimize the curvature radius of the corners in consideration of these variables.

For example, the greater the curvature radius of the corners is, the greater the effect of preventing small cracks may become. However, if the curvature radius of the corners becomes too large, a processing cost or time for rounding may be wasted. On the other hand, if the curvature radius of the corners becomes too small, the effect of preventing small cracks may be reduced.

As such, empirically, for example, the curvature radius of the corners for economically preventing small cracks may be greater than 3 micrometers but less than a half of the thickness of the substrate 10. In addition, this curvature radius of the corners is three-dimensionally configured and the corners may have domed surfaces. However, this curvature radius or shape of the corners is not limited to what is illustrated in FIG. 1 but may vary.

The corners of the substrate 10 may be rounded by dipping the substrate 10 into an etchant and chemically etching the corners.

Here, to expedite the rounding of the corners, the substrate 10 may be moved back and forth in a direction perpendicular to a length direction of the substrate 10 to make the etchant flow faster at the corners of the substrate 10. As such, the corners of the substrate 10 may be rounded more easily.

Alternatively, instead of using the above-described chemical method, the corners of the substrate 10 may be physically cut using various polishing machines.

The substrate 10 is capable of accommodating the light emitting device 30, is electrically insulated from the light emitting device 30 by the insulating layer 11, and may be formed of a material having an appropriate mechanical strength to support the light emitting device 30.

For example, the substrate 10 may be formed of aluminum (Al), copper (Cu), zinc (Zn), tin (Sn), lead (Pb), gold (Au), silver (Ag) or the like having excellent thermal conductivity and capable of being insulated, and formed as a plate-type or lead-frame-type substrate.

Alternatively, the substrate 10 may be a thin flexible printed circuit board (FPCB).

Other than that set forth above, the substrate 10 may include metal and partly include synthetic resin such as resin or glass epoxy, or include a ceramic material in consideration of thermal conductivity, or include one or more materials selected from the group consisting of epoxy mold compound (EMC), polyimide (PI), graphene, synthetic glass fiber and combinations thereof to improve processability.

The insulating layer 11 is an insulator formed on the surfaces of the substrate 10 to completely or partially surround the substrate 10, and may be formed by oxidizing the substrate 10. If the substrate 10 includes aluminum, the insulating layer 11 may include alumina, which is an aluminum oxide material. Various oxidizing methods may be used here. For example, the insulating layer 11 may be formed by oxidizing an aluminum component on the surfaces of the substrate 10 using an anodizing method.

That is, the substrate 10 may include an aluminum component and the insulating layer 11 may be an aluminum oxide layer. Here, the insulating layer 11 may be formed on all the surfaces, including the corners, of the substrate 10, or may be formed except for cut surfaces of the bridges 40 which fix the substrate 10 for oxidization. Alternatively, the insulating layer 11 may be formed of silicon oxide or silicon nitride, and formed by a printing method such as jet printing.

The first and second electrode layers 20-1 and 20-2 may be formed on the insulating layer 11 to face the light emitting device 30, and an electrode separating line L may be formed between the first and second electrode layers 20-1 and 20-2.

Particularly, for example, as illustrated in FIGS. 1 to 3, each of the first and second electrode layers 20-1 and 20-2 may be formed on the top, both side and bottom surfaces of the insulating layer 11 that surrounds the substrate 10.

That is, as illustrated in FIG. 1, upper parts of the first and second electrode layers 20-1 and 20-2, which have semicircular reflection parts R1 and R2 at both sides relative to the electrode separating line L, may be formed on the top surface of the insulating layer 11 that surrounds the substrate 10.

Furthermore, lower parts of the first and second electrode layers 20-1 and 20-2 may be formed on the bottom surface of the insulating layer 11 that surrounds the substrate 10. Here, although not shown in FIG. 1, the lower parts of the first and second electrode layers 20-1 and 20-2 may be formed to correspond to the shape of an external power connector or a module substrate to be electrically connected thereto.

Besides, a first side electrode 21 and a second side electrode 22 may be formed on the side surfaces of the insulating layer 11 that surrounds the substrate 10 such that the upper parts of the first and second electrode layers 20-1 and 20-2 and the lower parts of the first and second electrode layers 20-1 and 20-2 are electrically connected to each other.

Here, the first and second side electrodes 21 and 22 have symmetrical trapezoidal shapes as illustrated in FIG. 3 because metal particles that form the first and second electrode layers 20-1 and 20-2 are dispersed to the trapezoidal shapes while passing through clearance holes of flat masks in a sputtering process for forming the first and second side electrodes 21 and 22.

The method for manufacturing the first and second side electrodes 21 and 22 are not limited to the sputtering method and coating conductive paste such as solder paste on the insulating layer 11, ultra-precision transfer or ultra-precision stamping, or various printing methods such as inkjet printing, stencil printing and squeeze printing, may be used.

The first and second electrode layers 20-1 and 20-2 may be formed of electrically conductive materials such as copper (Cu), gold (Au), silver (Ag), platinum (Pt), aluminum (Al) or solder, and may also be formed by various processes such as a deposition process, a plating process such as pulse plating or direct current plating, a soldering process, a bonding process and a spraying process.

As illustrated in FIGS. 1 to 3, the light emitting device 30 may be a light emitting diode (LED) mounted on the first and second electrode layers 20-1 and 20-2 such that a first terminal 31 is electrically connected to the first electrode layer 20-1 and a second terminal 32 is electrically connected to the second electrode layer 20-2.

Here, as illustrated in FIG. 1, the light emitting device 30 may be a flip-chip LED, which needs no bonding wire.

Furthermore, a first electrode pad and a second electrode pad, to which boding wires can be connected, may be formed on a surface of the light emitting device 30, and an insulative bonding medium may be formed on another surface of the light emitting device 30.

The light emitting device 30 may have a horizontal shape or a vertical shape, include various signal transmission media such as bumps and solders, and include various-type light emitting devices.

Although only one light emitting device 30 is mounted on the top surfaces of the first and second electrode layers 20-1 and 20-2 in FIG. 1, a plurality of light emitting devices 30 may be mounted on the substrate 10.

The light emitting device 30 may be made of a semiconductor. For example, the light emitting device 30 may include an LED made of a nitride semiconductor and emitting blue, green, red and yellow light, an LED emitting ultraviolet light, or an LED emitting infrared light. The general formula for the nitride semiconductor is AlₓGa_{y}In_{z}N(0≦x≦1, 0≦y≦1, 0≦z≦1, x+y+z=1).

Furthermore, the light emitting device 30 may be formed by, for example, epitaxially growing a nitride semiconductor such as InN, AlN, InGaN, AlGaN or InGaAlN on a growth substrate such as a sapphire or silicon carbide (SiC) substrate using a vapor deposition method such as metal organic chemical vapor deposition (MOCVD). Alternatively, the light emitting device 30 may be formed by using a semiconductor such as ZnO, ZnS, ZnSe, SiC, GaP, GaAlAs or AlInGaP other than the nitride semiconductor. These semiconductors may include a stacked structure in which an n-type semiconductor layer, a light-emitting layer and a p-type semiconductor layer are sequentially provided. The light-emitting layer (active layer) may include a staked semiconductor having a multi-quantum well structure or a single quantum well structure, or a staked semiconductor having a double heterostructure. In addition, the light emitting device 30 may select one of an arbitrary wavelength depending on the usage thereof, e.g., display or lighting.

Here, the growth substrate may include an insulating, electrically conductive or semiconductor substrate where necessary. For example, the growth substrate may be a sapphire, SiC, Si, MgAl₂O₄, MgO, LiAlO₂, LiGaO₂, or GaN substrate. For epitaxial growth of a GaN material, a GaN substrate which includes the same material as the GaN material may be appropriate, but it is problematic that the manufacturing cost for GaN is high due to difficulties in manufacturing.

A sapphire or SiC substrate is often used other than the GaN substrate, and the sapphire substrate is more commonly used than the SiC substrate which is more expensive. When the substrate other than the GaN substrate is used, defects such as dislocations are increased due to the differences in lattice constants between the substrate material and the thin film material. In addition, when temperature varies, warpage occurs due to the differences in thermal expansion coefficients between the substrate material and the thin film material, thereby causing cracks in the thin film. This problem can be reduced by using a buffer layer between the substrate and the GaN-based light-emitting laminate.

The growth substrate may be completely or partially eliminated or patterned in a chip manufacturing procedure before or after the growth of an LED structure to improve optical or electrical properties of an LED chip.

For example, a sapphire substrate may be separated by projecting a laser beam through the substrate onto the interface with the semiconductor layer, and a silicon (Si) or silicon carbide (SiC) substrate may be eliminated by a polishing or etching method.

In other embodiments, a supporting substrate may be used when the growth substrate is eliminated. The supporting substrate may be formed by bonding a reflective metal or inserting a reflection structure into a bonding layer on the original growth substrate to improve light efficiency of the LED chip.

Furthermore, patterning of the growth substrate improves light extraction efficiency by making main surfaces (top surface, or top and bottom surfaces) or side surfaces of the substrate uneven or inclined before or after the growth of the LED structure. The patterns may have a size selected from a range of 5 nm to 500 μm and include regular or irregular patterns as long as light extraction efficiency is improved. The patterns may have a variety of shapes such as poles, mountains, hemispheres and polygons.

The sapphire substrate is a crystal body having Hexa-Rhombo (Hexa-Rhombo R3c) symmetry. The sapphire has a lattice constant of 13.001 Å in c-axis orientation, and a lattice constant of 4.758 Å in a-axis orientation; and has a C-plane, A-plane and R-plane. Here, the C-plane of this sapphire substrate allows a nitride thin film to be grown thereupon relatively easily and is stable even at high temperatures, thus it is predominantly utilized as a substrate for nitride growth.

Another example of the growth substrate is a Si substrate. The Si substrate is appropriate for a large diameter substrate and relatively cheap, thus advantageous for mass production.

Since the silicon (Si) substrate absorbs light generated by a GaN-based semiconductor and thus external quantum efficiency of the light emitting device decreases, the silicon substrate is eliminated if necessary and a supporting substrate including a reflection layer and formed of Si, Ge, SiAl, ceramic or metal is additionally formed and used.

When a GaN thin film is grown on a non-GaN substrate such as the Si substrate, the density of dislocation may be increased due to the differences in lattice constants between the substrate material and the thin film material, and cracks and warpage may occur due to the differences in thermal expansion coefficients therebetween. A buffer layer may be disposed between the growth substrate and the light-emitting laminate to prevent generation of dislocations and cracks of the light-emitting laminate. The buffer layer also decreases wavelength dispersion of wafers by controlling the degrees of warpage of the substrate when the active layer grows.

Here, the buffer layer may be made of a material having a composition of AlₓIn_{y}Ga_{1-x-y}N (0≦x≦1, 0≦y≦1, and x+y≦1). More particularly, GaN, AlN, AlGaN, InGaN or InGaNAlN may be used therefor, or ZrB₂, HfB₂, ZrN, HfN, TiN or the like may be used therefor, if necessary. Furthermore, the buffer layer may be formed by combining a plurality of layers or gradually varying the composition thereof.

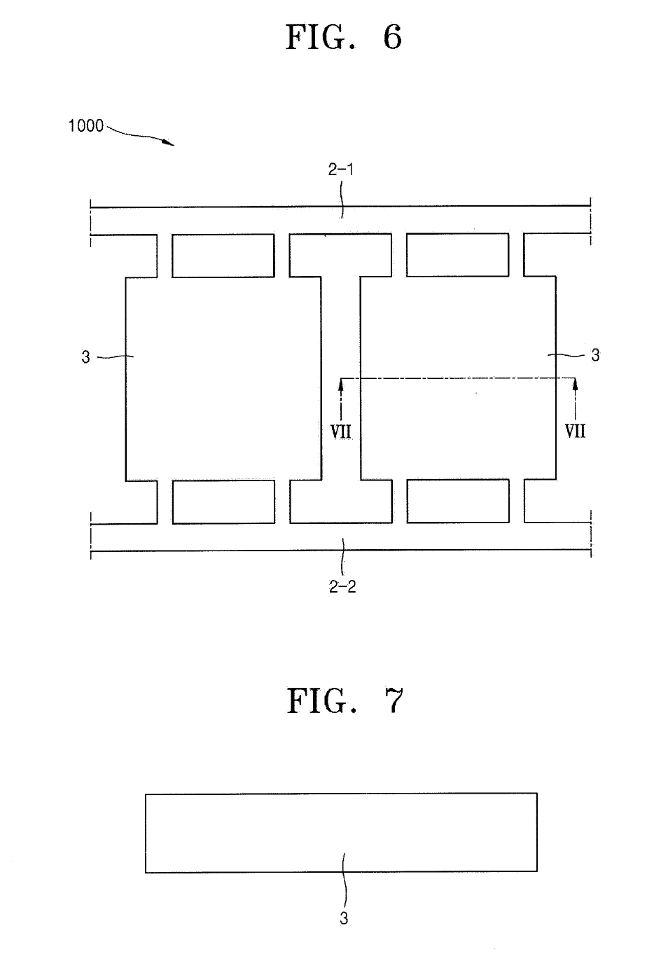

As illustrated in FIGS. 1 to 3, the bridges 40 may be structures having cut surfaces 40a at sides thereof and protruding from the side surfaces of the substrate 10 or the insulating layer 11 by a margin length D such that small cracks generated when a substrate strip 1000 (see FIG. 6) is cut is prevented from propagating to the substrate 10 or the insulating layer 11.

Here, the margin length D may vary depending on the size, shape, material, processing environment, etc. of the substrate 10. Accordingly, the margin length D may be optimized in consideration of these variables.

For example, the greater the margin length D is, the greater the effect of preventing propagation of small cracks may become. However, if the margin length D is excessively large, the size of a product size may be increased and therefore the material for the product may be wasted. On the other hand, if the margin length D is excessively small, the effect of preventing propagation of small cracks may be reduced.

As such, empirically, for example, the margin length D for economically preventing propagation of small cracks may be greater than at least 3 micrometers but less than a half of the thickness of the substrate 10. In addition, this margin length D is three-dimensionally applicable to both height and width. Particularly, for example, the bridge 40 may be formed as a substantially hexahedral protrusion having a width of 100 micrometers to 600 micrometers and a margin length D of 200 micrometers to 300 micrometers. However, this size or shape of the bridges 40 is not limited to that illustrated in FIG. 1 but may be variously changed to, for example, an inclined shape or a very thin shape.

The bridges 40 are cut by a cutting tool along cutting lines C1 and C2 of FIG. 20, and the remaining cut surfaces 40a of the substrate 10 and the insulating layer 11 may be exposed.

Accordingly, although small cracks are generated in some parts of the substrate 10 or the insulating layer 11 when the cutting tool cuts the substrate strip 1000 along the cutting lines C1 and C2 of FIG. 20, the small cracks may be generated only in the bridges 40 and do not propagate further because cracks propagate easily in a straight line but not on curved surfaces.

That is, since the small cracks only remain near the cut surfaces 40a of the bridges 40 and do not propagate further, malfunction of terminals, e.g., short circuit, may be prevented and product strength, durability or other properties may be greatly improved.

As illustrated in FIGS. 1 to 3, various methods such as molding, printing, dispensing and etching may be utilized to form a ring-shaped dam 50 may be formed around the reflection parts R1 and R2 of the first and second electrode layers 20-1 and 20-2, which is substantially circular in shape.

A lens 60 or a phosphor may be formed inside the dam to surround the light emitting device 30.

Here, a lens material or a phosphor material may be coated or dispensed inside the dam 50 to allow the lens 60 or the phosphor to be easily formed inside the dam 50.

However, the light emitting device package 100 according to an embodiment of the present invention is not limited to the lens 60 or the phosphor which is coated or dispensed inside the dam 50, and the lens 60 or the phosphor may be molded without the dam 50.

The lens 60 is capable of guiding the path of light generated from the light emitting device 30, and may include glass, epoxy resin composition, silicone resin composition, modified epoxy resin composition such as silicone-modified epoxy resin, modified silicone resin composition such as epoxy-modified silicone resin, polyimide resin composition, modified polyimide resin composition, polyphthalamide (PPA), polycarbonate resin, polyphenylene sulfide (PPS), liquid crystal polymer (LCP), acrylonitrile butadiene styrene (ABS) resin, phenol resin, acrylic resin, polybutylene terephthalate (PBT) resin, or the like.

The phosphor may be formed to have the same shape as the lens 60, or may be included in the lens 60, and may be formed near the light emitting device 30.

The phosphor may have compositions and colors as described below.

Oxide-based: yellow and green Y₃Al₅O₁₂:Ce, Tb₃Al₅O₁₂:Ce, Lu₃Al₅O₁₂:Ce

Silicate-based: yellow and green (Ba,Sr)₂SiO₄:Eu, yellow and orange (Ba,Sr)₃SiO₅:Ce

Nitride-based: green β-SiAlON:Eu, yellow L₃Si₆O₁₁:Ce, orange α-SiAlON:Eu, red CaAlSiN₃:Eu, Sr₂Si₅N₈:Eu, SrSiAl₄N₇:Eu

The above compositions of the phosphor should basically comply with stoichiometry, and each element is replaceable with another element of the same group in the periodic table. For example, Sr is replaceable with Ba, Ca or Mg of alkaline earth group (Group II), and Y is replaceable with lanthanum-based Tb, Lu, Sc or Gd. Furthermore, Eu which is an activator is replaceable with Ce, Tb, Pr, Er or Yb based on a desired energy level, and the activator may be used solely or together with a co-activator for property modification.

A substitute for the phosphor includes a material such as quantum dots (QDs), and the phosphor and the QDs may be used solely or together for the LED.

The QDs may be composed of cores (3 nm to 10 nm) of CdSe, InP or the like, shells (0.5 nm to 2 nm) of ZnS, ZnSe or the like, and ligands for stabilization of the cores and shells, and display a variety of colors based on sizes thereof.

The phosphor or the QDs may be coated on the LED chip or the light emitting device by using at least one of spraying, overlaying, and film or ceramic phosphor sheet bonding.

Dispensing or spray coating is commonly used as the spraying method, and the dispensing method includes mechanical methods such as pneumatic, screw and linear type dispensing. A jetting method allows control of a coating amount through small discharge and thus allows control of color coordinates. If the phosphor is coated at a wafer level or on the LED substrate using the spraying scheme, productivity and thickness control may be easily achieved.

The overlaying method directly on the light emitting device 30 or the LED chip may include electrophoresis, screen printing and molding, and these schemes may differ depending on whether side surfaces of the LED chip need to be coated.

Two or more phosphors having different emission wavelengths may be used to control the efficiency of a long-wavelength emission phosphor which absorbs light emitted at short wavelengths, and a distributed Bragg reflector (DBR) (or omnidirectional reflector (ODR)) layer may be inserted between every two layers to minimize wavelength re-absorption and interference of the LED chip and the two or more phosphors.

The phosphor may be formed as a film or ceramic and then bonded on the LED chip or the light emitting device 30 to form a uniform coating layer.

A photoconversion material may be located in a remote manner to provide a difference in light efficiency and light distribution properties. In this case, the photoconversion material is located together with a material such as light-transmitting polymer or glass depending on durability, heat resistance, etc. thereof.

This phosphor coating technology is a main factor for determining optical properties of the light emitting device 30, and thus research is being conducted on a variety of control technologies related to the thickness of a phosphor coating layer, uniform dispersion of a phosphor, etc. The QDs may also be located on the LED chip or the light emitting device 30 in the same manner as the phosphor, and may be disposed in glass or light-transmitting polymer to perform optical conversion.

Although not shown in FIGS. 1 to 3, various components such as a reflector, a light-transmitting encapsulant, a non-light-transmitting encapsulant, a filter, a light guide plate and a display panel may be additionally formed near the light emitting device 30.

Therefore, by rounding the corners of the substrate 10, generation of small cracks may be prevented and propagation of small cracks generated at the cut surfaces 40a, to other parts may also be prevented. As such, product performance and durability may be greatly improved and high-quality products may be produced.

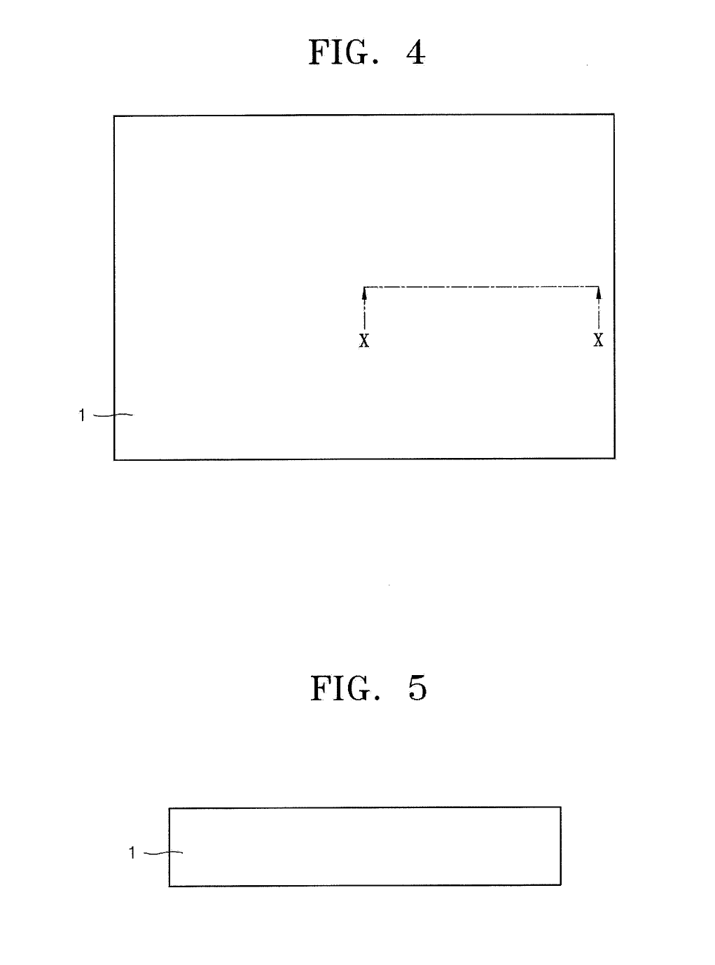

FIGS. 4 to 20 are views showing individual steps of a method of manufacturing the light emitting device package 100 of FIG. 1, according to an embodiment of the present invention.

FIG. 4 is a plan view showing a raw plate preparing step in the method of manufacturing the light emitting device package 100 of FIG. 1, according to an embodiment of the present invention, and FIG. 5 is a cross-sectional view taken along line X-X of FIG. 4.

As illustrated in FIGS. 4 and 5, initially, a raw plate 1 formed of a metallic material may be prepared.

Here, as illustrated in FIGS. 4 and 5, the raw plate 1 is a thin plate to be formed as the substrate strip 1000, and may be formed of, for example, 1000 or 5000 series aluminum capable of easily forming an oxide layer and having excellent processability and thermal conductivity.

FIG. 6 is a plan view showing a raw plate shaping step in the method of manufacturing the light emitting device package 100 of FIG. 1, according to an embodiment of the present invention, and FIG. 7 is a cross-sectional view taken along line VII-VII of FIG. 6.

Then, as illustrated in FIGS. 6 and 7, the raw plate 1 may be shaped into the substrate strip 1000 to form a first rail 2-1 and a second rail 2-2 at a side and another side of the raw plate 1, respectively, to form dies 3 at a middle part of the raw plate 1, to form at least one first bridge 41 between the first rail 2-1 and the die 3, and to form at least one second bridge 42 between the second rail 2-2 and the die 3.

Here, the first and second bridges 41 and 42 may be formed on front and rear surfaces of the die 3, and spaces for forming the first and second side electrodes 21 and 22 may be prepared on left and right surfaces of the die 3.

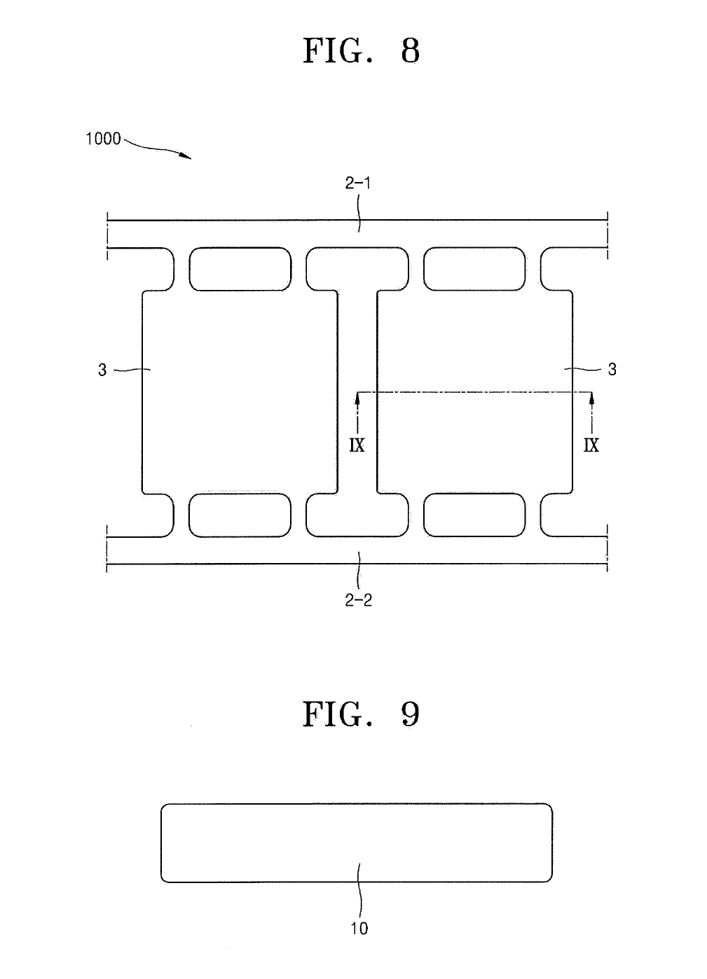

FIG. 8 is a plan view showing a surface-treating step in the method of manufacturing the light emitting device package 100 of FIG. 1, according to an embodiment of the present invention, and FIG. 9 is a cross-sectional view taken along line IX-IX of FIG. 8.

Then, as illustrated in FIGS. 8 and 9, the substrate strip 1000 may be surface-treated by dipping the substrate strip 1000 into an etchant and moving the substrate strip 1000 back and forth in a direction perpendicular to a length direction of the substrate strip 1000 to round off the corners of the dies 3 of the substrate strip 1000.

Here, instead of moving the substrate strip 1000 back and forth, various schemes for moving the substrate strip 1000, for example, rotating the substrate strip 100, may beutilized. Furthermore, instead of the above-described chemical etching scheme, the corners may be rounded by various schemes such as mechanical polishing.

As described above, small cracks that have already been generated at the corners may be eliminated by surface-treating the substrate strip 1000 or generation of small cracks may be prevented by rounding off the corners.

In addition, if the above-described surface-treatment may be utilized such that surface roughness of the substrate strip 1000 may be improved and various scratches or margins, e.g., burrs or flash, commonly produced at the corners due to processing errorsmay be clearly eliminated.

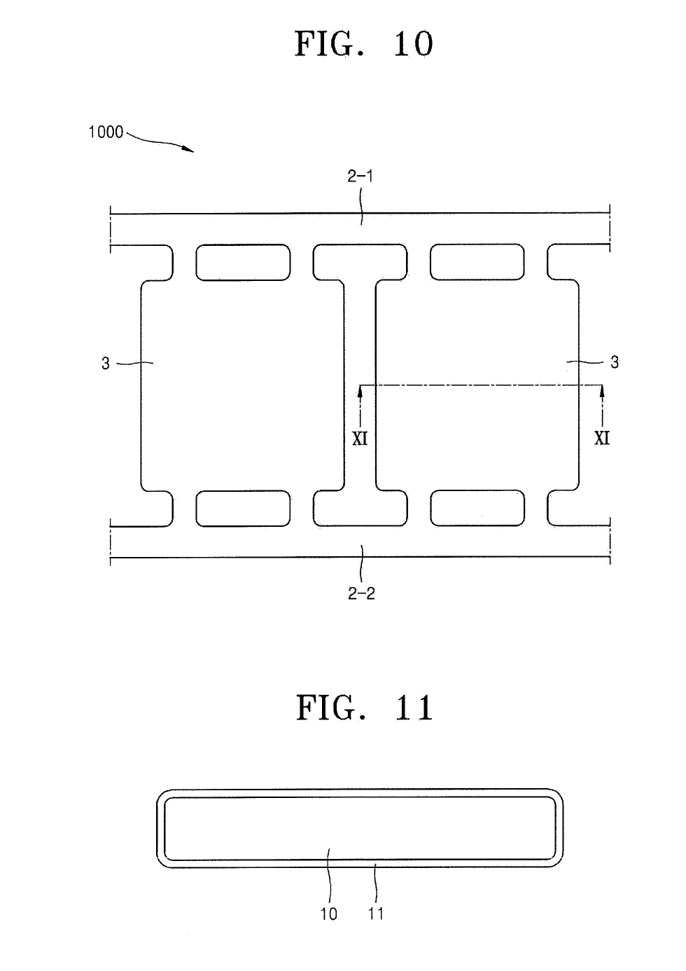

FIG. 10 is a plan view showing an insulating layer forming step in the method of manufacturing the light emitting device package 100 of FIG. 1, according to an embodiment of the present invention, and FIG. 11 is a cross-sectional view taken along line XI-XI of FIG. 10.

Then, as illustrated in FIGS. 10 and 11, the insulating layer 11 may be formed on the substrate strip 1000, the corners of which are rounded off.

Here, the insulating layer 11 may include alumina, which is an aluminum oxide material. Various oxidizing methods may be used here. For example, the insulating layer 11 may be formed by oxidizing an aluminum component on the surfaces of the substrate 10 using an anodizing method.

That is, the insulating layer 11 may be formed by oxidizing the surfaces of the substrate strip 1000, which is made of an aluminum material, using an anodizing method.

Here, the anodizing method refers to a method for performing electrolysis in an aqueous solution with a metal as an anode, to form a corrosion-resistant oxide film on the metal surface, and may be commonly used to form an aluminum oxide layer.

The aqueous solution may be an acidic electrolyte solution such as an aqueous solution of oxalic acid, sulfuric acid, phosphoric acid or chromic acid.

Meanwhile, an insulating layer mask may be selectively disposed such that the insulating layer 11 is not formed on part of the surfaces of the substrate strip 1000.

Here, the insulating layer 11 may not be formed on part of the surfaces of the substrate strip 1000 in order to increase thermal conductivity or light reflectivity.

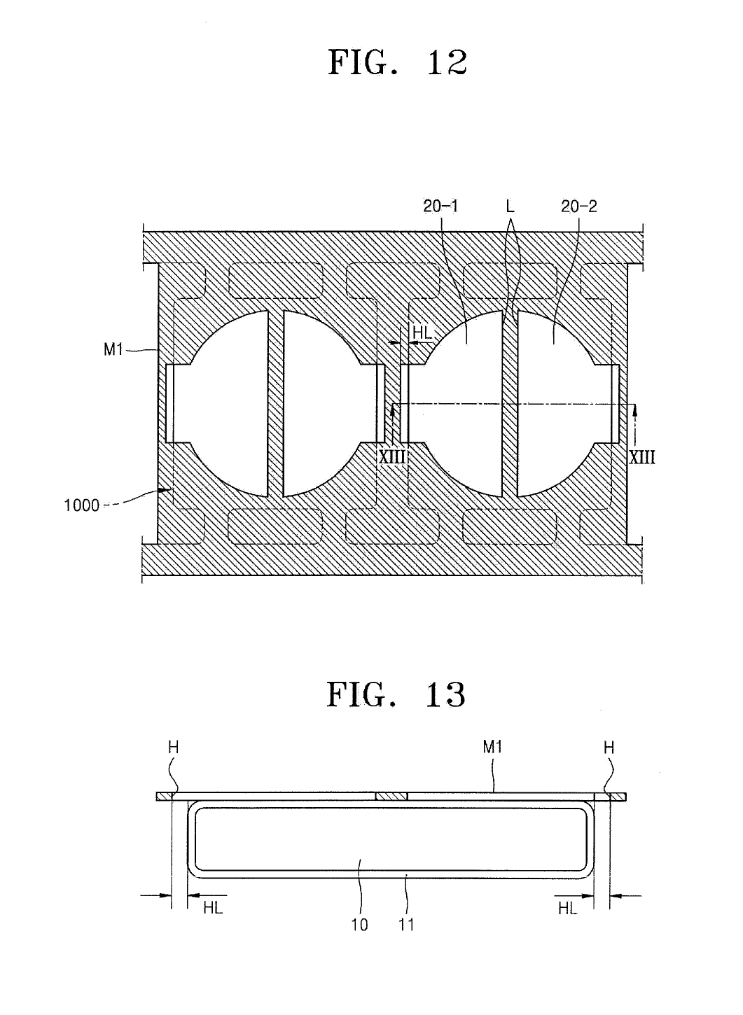

FIG. 12 is a plan view showing a first mask disposition step of an electrode layer forming step in the method of manufacturing the light emitting device package 100 of FIG. 1, according to an embodiment of the present invention, and FIG. 13 is a cross-sectional view taken along line XIII-XIII of FIG. 12.

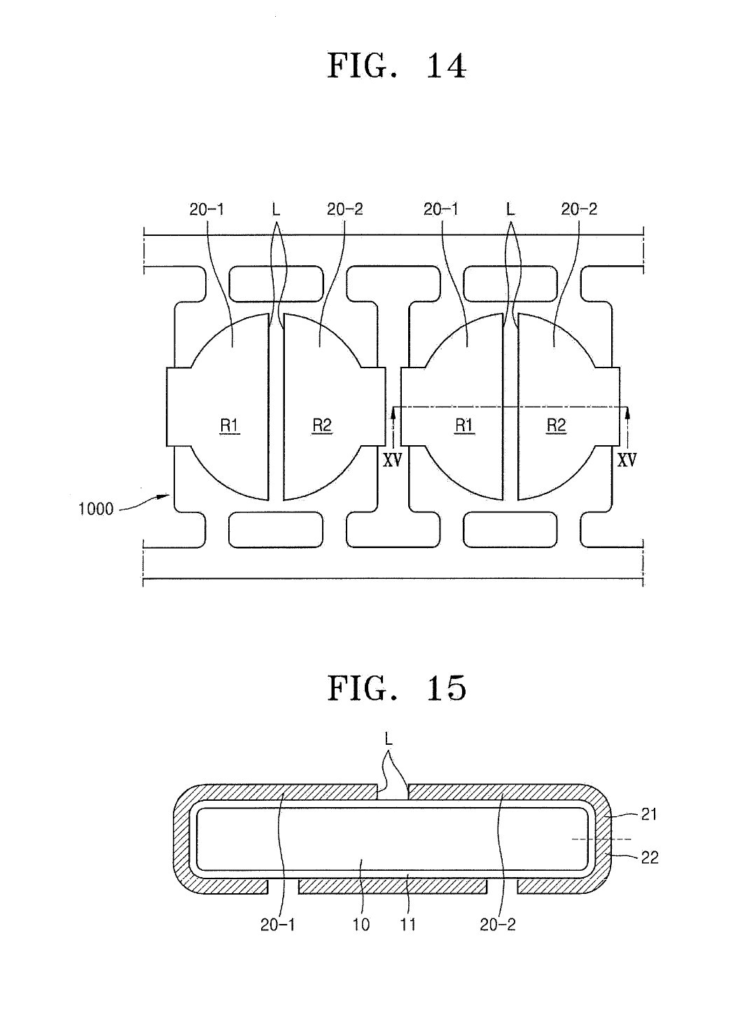

Furthermore, FIG. 14 is a plan view showing an upper electrode forming step or a lower electrode forming step of the electrode layer forming step in the method of manufacturing the light emitting device package 100 of FIG. 1, according to an embodiment of the present invention, and FIG. 15 is a cross-sectional view taken along line XV-XV of FIG. 14.

Then, as illustrated in FIGS. 12 to 15, the first and second electrode layers 20-1 and 20-2 separated by the electrode separating line L may be formed on the insulating layer 11 formed on the die 3 of the substrate strip 1000.

That is, a first mask M1 having a first pattern may be disposed on the insulating layer 11 such that upper parts of the first and second electrode layers 20-1 and 20-2 are formed on the insulating layer 11 formed on a top surface of the die 3 of the substrate strip 1000 as illustrated in FIGS. 12 and 13. Furthermore, the upper parts of the first and second electrode layers 20-1 and 20-2 may be formed on the insulating layer 11 through the first pattern of the first mask M1 by a sputtering method as illustrated in FIGS. 14 and 15.

Here, although not shown in the drawings, a second mask having a second pattern may be disposed on the insulating layer 11 such that lower parts of the first and second electrode layers 20-1 and 20-2 are formed on the insulating layer 11 formed on a bottom surface of the die 3 of the substrate strip 1000. Furthermore, the lower parts of the first and second electrode layers 20-1 and 20-2 may be formed on the insulating layer 11 through the second pattern of the second mask by using a sputtering method.

Here, as illustrated in FIGS. 12 and 13, side clearance holes H may be formed in the first pattern of the first mask M1 such that the upper and lower parts of the first and second electrode layers 20-1 and 20-2 are electrically connected to each other, and the first side electrode 21 may be formed on side surfaces of the die 3 of the substrate strip 1000 through the side clearance holes H.

Likewise, side clearance holes may be formed in the second pattern of the second mask, and the second side electrode 22 may be formed on the side surfaces of the die 3 of the substrate strip 1000 through the side clearance holes, to be electrically connected to the first side electrode 21.

Although not shown in the drawings, a conductive paste may be printed or pad printed to form the first and second electrode layers 20-1 and 20-2.

Here, a pad printing refers to a method performed on an object having a curved or 3-dimensional (3D) surface, and refers to a scheme for transferring a printing pigment onto surfaces of a pad formed of an elastic material and then pressing the pad onto the object to perform printing. Accordingly, using this pad printing scheme, the first and second electrode layers 20-1 and 20-2 may be formed even on side surfaces of the insulating layer 11.

The first and second side electrodes 21 and 22 of the first and second electrode layers 20-1 and 20-2 may also be formed by using a three-dimensional mask(s) instead of the first mask M1 and the second mask once or twice.

Here, the three-dimensional mask may be disposed on surfaces of the insulating layer 11 using various schemes such as 3D printing, molding, bonding, pad printing and coating.

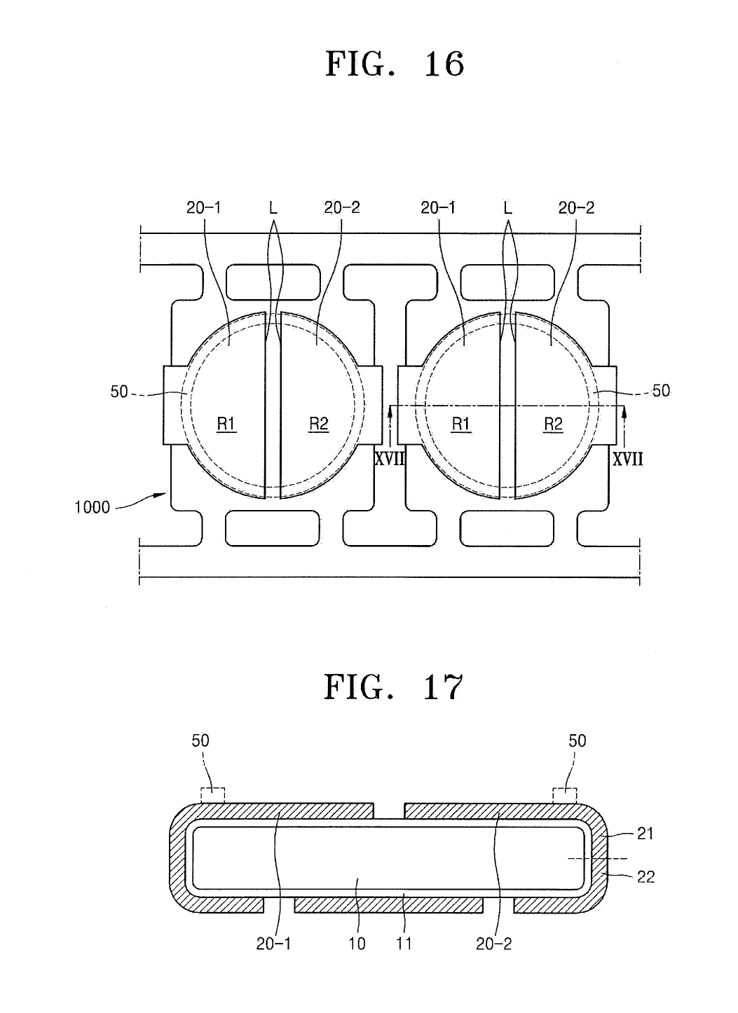

FIG. 16 is a plan view showing a dam forming step in the method of manufacturing the light emitting device package 100 of FIG. 1, according to an embodiment of the present invention, and FIG. 17 is a cross-sectional view taken along line XVII-XVII of FIG. 16.

Then, as illustrated in FIGS. 16 and 17, the ring-shaped dam 50 may be formed around the reflection parts R1 and R2, which are substantially circular in shape, of the first and second electrode layers 20-1 and 20-2, by using various methods such as molding, printing, dispensing and etching.

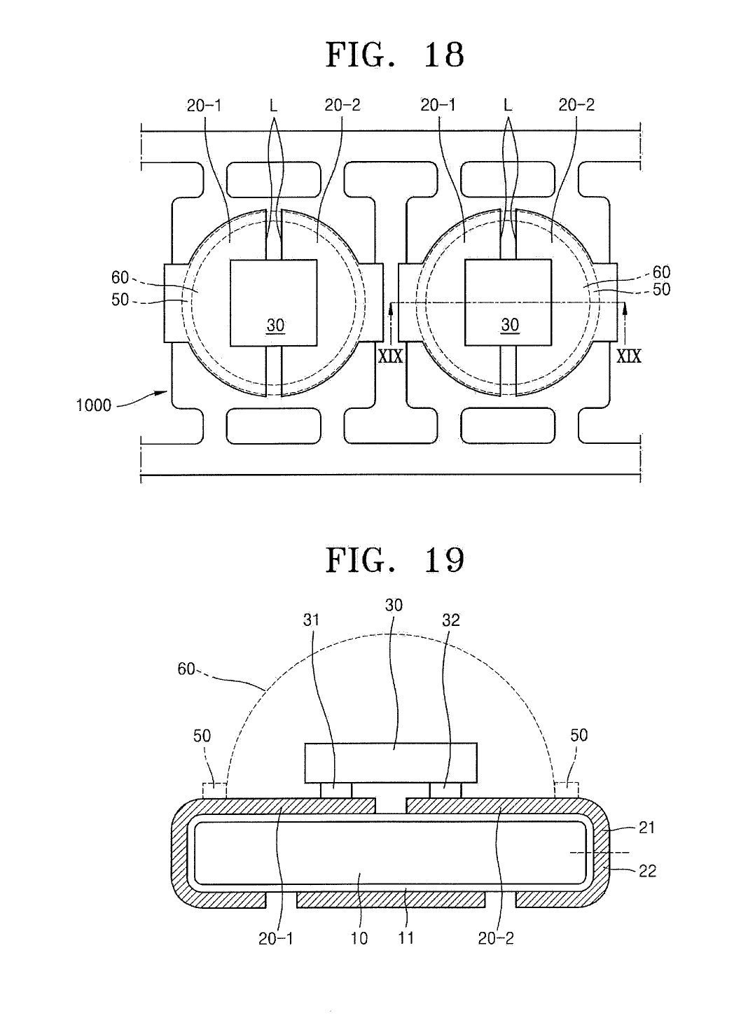

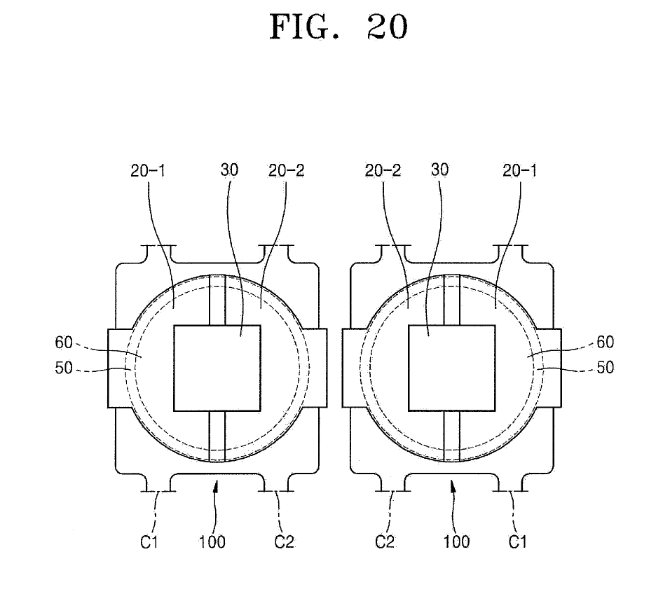

FIG. 18 is a plan view showing a lens forming step in the method of manufacturing the light emitting device package 100 of FIG. 1, according to an embodiment of the present invention, and FIG. 19 is a cross-sectional view taken along line XIX-XIX of FIG. 18.

Then, as illustrated in FIGS. 18 and 19, the light emitting device 30 may be mounted on the first and second electrode layers 20-1 and 20-2 such that the first terminal 31 of the light emitting device 30 is electrically connected to the first electrode layer 20-1 and the second terminal 32 of the light emitting device 30 is electrically connected to the second electrode layer 20-2.

Then, as illustrated in FIGS. 18 and 19, the lens material or the phosphor material may be coated or dispensed inside the dam 50 to allow the lens 60 or the phosphor to surround the light emitting device 30.

FIG. 20 is a plan view showing a bridge cutting step in the method of manufacturing the light emitting device package 100 of FIG. 1, according to an embodiment of the present invention.

Then, as illustrated in FIG. 20, the cutting line C1 of the first bridge 41 and the cutting line C2 of the second bridge 42 may be cut to individualize the light emitting device 30 and the die 3 of the substrate strip 1000 into the light emitting device package 100.

Here, the cutting lines C1 and C2 spaced apart from the die 3 by the margin length D may be cut by using a sawing process or a trimming process to prevent small cracks that are generated when the bridges 40 are cut from propagating to the die 3.

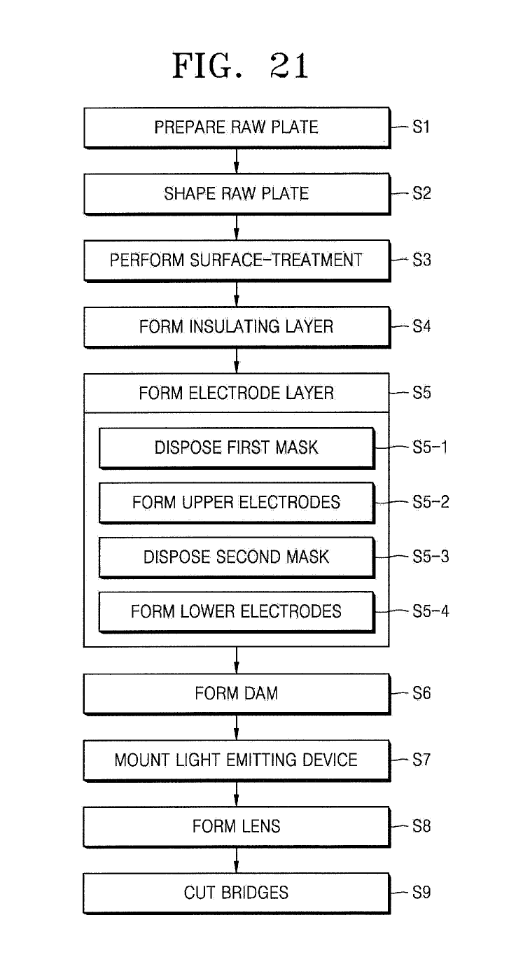

FIG. 21 is a flowchart of a method of manufacturing the light emitting device package 100 of FIG. 1, according to an embodiment of the present invention.

As illustrated in FIGS. 1 to 21, the method of manufacturing the light emitting device package 100 according to an embodiment of the present invention may include a raw plate preparing step S1 for preparing the raw plate 1 formed of a metallic material, a raw plate shaping step S2 for shaping the raw plate 1 into the substrate strip 1000 to form the first and second rails 2-1 and 2-2 at a side and another side of the raw plate 1, respectively, to form the dies 3 at a middle part of the raw plate 1, to form at least one first bridge 41 between the first rail 2-1 and each die 3, and to form at least one second bridge 42 between the second rail 2-2 and the die 3, a surface-treating step S3 for surface-treating the substrate strip 1000, an insulating layer forming step S4 for forming the insulating layer 11 on the surface-treated substrate strip 1000, an electrode layer forming step S5 for forming the first and second electrode layers 20-1 and 20-2 separated by the electrode separating line L, on the insulating layer 11 formed on the die 3 of the substrate strip 1000, a dam forming step S6 for forming the ring-shaped dam 50 around the reflection parts R1 and R2 of the first and second electrode layers 20-1 and 20-2, a light emitting device mounting step S7 for mounting the light emitting device 30 on the first and second electrode layers 20-1 and 20-2 to electrically connect the first terminal 31 of the light emitting device 30 to the first electrode layer 20-1 and to electrically connect the second terminal 32 of the light emitting device 30 to the second electrode layer 20-2, a lens forming step S8 for coating or dispensing the lens material or the phosphor material inside the dam 50 to allow the lens 60 or the phosphor to surround the light emitting device 30, and a bridge cutting step S9 for cutting the cutting line C1 of the first bridge 41 and the cutting line C2 of the second bridge 42 to individualize the light emitting device 30 and the die 3 of the substrate strip 1000 into the light emitting device package 100.

Specifically, for example, in the surface-treating step S3, the substrate strip 1000 may be dipped into an etchant and moved back and forth in a direction perpendicular to a length direction of the substrate strip 1000 to round corners of the dies 3 of the substrate strip 1000.

In the insulating layer forming step S4, the insulating layer 11 may be formed by oxidizing the surfaces of the substrate strip 1000 formed of an aluminum material, using an anodizing scheme.

Furthermore, in the insulating layer forming step S4, an insulating layer mask may be disposed not to form the insulating layer 11 on parts of the surfaces of the substrate strip 1000.

The electrode layer forming step S5 may include a first mask disposition step S5-1 for disposing the first mask M1 having the first pattern on the insulating layer 11 to correspond to upper parts of the first and second electrode layers 20-1 and 20-2 to be formed on the insulating layer 11 formed on a top surface of the die 3 of the substrate strip 1000, an upper electrode forming step S5-2 for forming the upper parts of the first and second electrode layers 20-1 and 20-2 on the insulating layer 11 through the first pattern of the first mask M1 using a sputtering scheme, a second mask disposition step S5-3 for disposing the second mask having the second pattern on the insulating layer 11 to correspond to lower parts of the first and second electrode layers 20-1 and 20-2 to be formed on the insulating layer 11 formed on a bottom surface of the die 3 of the substrate strip 1000, and a lower electrode forming step S5-4 for forming the lower parts of the first and second electrode layers 20-1 and 20-2 on the insulating layer 11 through the second pattern of the second mask using a sputtering scheme.

The side clearance holes H may be formed in the first pattern of the first mask M1 to electrically connect the upper and lower parts of the first and second electrode layers 20-1 and 20-2 to each other in the first mask disposition step S5-1, the first side electrode 21 may be formed on side surfaces of the die 3 of the substrate strip 1000 through the side clearance holes H in the upper electrode forming step S5-2, the side clearance holes may be formed in the second pattern of the second mask in the second mask disposition step S5-3, and the second side electrode 22 may be formed on the side surfaces of the die 3 of the substrate strip 1000 through the side clearance holes, to be electrically connected to the first side electrode 21 in the lower electrode forming step S5-4.

In the electrode layer forming step S5, the first and second electrode layers 20-1 and 20-2 may also be formed by printing or pad-printing conductive paste.

Here, the pad printing scheme may be performed on an object having a curved or 3-dimensional (3D) surface, and refers to a scheme for transferring a printing pigment onto a surfaces of a pad formed of an elastic material and then pressing the pad onto the object to perform printing. Accordingly, using this pad printing scheme, the first and second electrode layers 20-1 and 20-2 may be formed even on side surfaces of the insulating layer 11.

In the bridge cutting step S9, the cutting lines C1 and C2 of the bridges 40 spaced apart from the die 3 by the margin length D may be cut to prevent propagation of small cracks generated when the bridges 40 are cut, to the die 3.

While the present invention has been particularly shown and described with reference to exemplary embodiments thereof, it will be understood by one of ordinary skill in the art that various changes in form and details may be made therein without departing from the spirit and scope of the present invention as defined by the following claims.

What is claimed is:

1. A method of manufacturing a light emitting device package, the method comprising:
a raw plate preparing step for preparing a raw plate formed of a metallic material;
a raw plate shaping step for shaping the raw plate into a substrate strip to form a first rail and a second rail at a side and another side of the raw plate, respectively, to form dies at a middle part of the raw plate, to form at least one first bridge between the first rail and the die, and to form at least one second bridge between the second rail and the die;
a surface-treating step for surface-treating the substrate strip;
an insulating layer forming step for forming an insulating layer on the surface-treated substrate strip; and
an electrode layer forming step for forming a first electrode layer and a second electrode layer separated by an electrode separating line, on the insulating layer formed on the die of the substrate strip.

2. The method of claim 1, wherein, in the surface-treating step, the substrate strip is dipped into an etchant and moved back and forth in a direction perpendicular to a length direction of the substrate strip to round off corners of the dies of the substrate strip.

3. The method of claim 1, wherein, in the insulating layer forming step, the insulating layer is formed by oxidizing surfaces of the substrate strip formed of an aluminum material, using an anodizing method.

4. The method of claim 1, wherein the electrode layer forming step comprises:
a first mask disposition step for disposing a first mask having a first pattern on the insulating layer such that upper parts of the first and the second electrode layers are formed on the insulating layer formed on a top surface of the die of the substrate strip;
an upper electrode forming step for forming the upper parts of the first and the second electrode layers on the insulating layer through the first pattern of the first mask by using a sputtering method;
a second mask disposition step for disposing a second mask having a second pattern on the insulating layer such that lower parts of the first and the second electrode layers are formed on the insulating layer formed on a bottom surface of the die of the substrate strip; and
a lower electrode forming step for forming the lower parts of the first and the second electrode layers on the insulating layer through the second pattern of the second mask by using a sputtering method.

5. The method of claim 4,
wherein side clearance holes are formed at the first pattern of the first mask such that the upper and the lower parts of the first and the second electrode layers are electrically connected to each other, respectively, in the first mask disposition step,
wherein a first side electrode is formed on side surfaces of the die of the substrate strip through the side clearance holes, in the upper electrode forming step,
wherein side clearance holes are formed at the second pattern of the second mask, in the second mask disposition step, and
wherein a second side electrode is formed on the side surfaces of the die of the substrate strip through the side clearance holes, to be electrically connected to the first side electrode, in the lower electrode forming step.

6. The method of claim 1, further comprising:
a dam forming step for forming a ring-shaped dam around reflection parts of the first and the second electrode layers;
a light emitting device mounting step for mounting a light emitting device on the first and the second electrode layers; and
a lens forming step for coating or dispensing a lens material or a phosphor material inside the dam to allow a lens or a phosphor to surround the light emitting device,
after the electrode layer forming step.

7. The method of claim 1, further comprising:
a light emitting device mounting step for mounting a light emitting device on the first and the second electrode layers; and
a bridge cutting step for cutting a cutting line of the first bridge and a cutting line of the second bridge to individualize the light emitting device and the die of the substrate strip into the light emitting device package,
wherein, in the bridge cutting step, the cutting lines of the first and the second bridges spaced apart from the die by a margin length are cut to prevent small cracks generated when the first and the second bridges are cut from propagating to the die.

8. The method of claim 1, wherein, in the insulating layer forming step, an insulating layer mask is disposed such that the insulating layer is not formed on a part of the surfaces of the substrate strip.

9. The method of claim 1, wherein, in the electrode layer forming step, a conductive paste is printed or pad printed to form the first and the second electrode layers.

10. A light emitting device package comprising:
a substrate formed of a metallic material and having rounded corners;
an insulating layer formed on surfaces of the substrate;
a first electrode layer and a second electrode layer formed on the insulating layer and separated by an electrode separating line;
a light emitting device mounted on the first and the second electrode layers; and
bridges having cut surfaces at sides thereof and protruding from side surfaces of the substrate or the insulating layer by a margin length to prevent small cracks generated when a substrate strip is cut from propagating to the substrate or the insulating layer.
